(19) United States
(12) Patent Application Publication
(10) Pub. No.: US 2020/0095672 A1
(43) Pub. Date: Mar. 26, 2020

(54) DEPOSITION METHOD AND ROLL-TO-ROLL DEPOSITION APPARATUS

(71) Applicant: ULVAC, INC., Chigasaki-shi, Kanagawa (JP)

(72) Inventors: Hiroaki HONMA, Chigasaki-shi, Kanagawa (JP); Hirohisa TAKAHASHI, Chigasaki-shi, Kanagawa (JP); Masaki HASEGAWA, Chigasaki-shi, Kanagawa (JP)

(21) Appl. No.: 16/468,097

(22) PCT Filed: Nov. 14, 2017
(86) PCT No.: PCT/JP2017/040975

§ 371 Date: Jun. 10, 2019

(30) Foreign Application Priority Data
Jan. 5, 2017 (JP) 2017-000715

(51) Int. Cl. C23C 14/56; C23C 14/20; C23C 14/34

(52) U.S. Cl. CPC C23C 14/56; C23C 14/34; C23C 14/205

(57) ABSTRACT

In order to suppress deformation of a flexible substrate, a deposition method according to an embodiment of the present invention includes pre-treatment of exhausting a vacuum chamber until a water partial pressure inside the vacuum chamber becomes equal to or lower than a desired value. Plasma is generated by applying an alternate current (AC) voltage between a first chromium target and a second chromium target, the first chromium target and the second chromium target being arranged inside the vacuum chamber. A chromium layer is formed on a deposition surface of a flexible substrate arranged facing the first chromium target and the second chromium target.

### TECHNICAL FIELD

The present invention relates to a deposition method and a roll-to-roll deposition apparatus.

### BACKGROUND ART

Regarding an electronic component or the like including a metal wire having a multi-layer structure is patterned on a base material, an adhesion layer is formed between the base material and the metal wire in some cases.

For example, there is a technology in which a chromium (Cr) layer is formed in advance as an adhesion layer on a base material and a multi-layer film is formed on this chromium layer (e.g., see Patent Literature 1). In this technology, internal stress of the chromium layer is reduced in order to improve the function of the chromium layer as the adhesion layer. For example, the oxygen concentration when the chromium layer is formed as a film is set to be lower and a chromium layer having reduced internal stress is formed between the base material and the multi-layer film.

### CITATION LIST

### Patent Literature

Patent Literature 1: Japanese Patent Application Laid-open No. 2010-126807

### DISCLOSURE OF INVENTION

### Technical Problem

However, even in a case where the oxygen concentration in the film deposition is set to be lower, the internal stress of the chromium layer may increase under some deposition conditions. Further, if an underlayer for the chromium layer is a flexible substrate, the flexible substrate is deformed due to the influence of the chromium layer.

In view of the above-mentioned circumstances, it is an object of the present invention to provide a deposition method and a roll-to-roll deposition apparatus in which deformation of the flexible substrate is suppressed by forming a chromium layer having reduced internal stress on a flexible substrate.

### SOLUTION TO PROBLEM

In order to accomplish the above-mentioned object, a deposition method according to an embodiment of the present invention includes pre-treatment of exhausting a vacuum chamber until a water partial pressure inside the vacuum chamber becomes equal to or lower than a desired value. Plasma is generated by applying an alternate current (AC) voltage between a first chromium target and a second chromium target, the first chromium target and the second chromium target being disposed inside the vacuum chamber. A chromium layer is formed on a deposition surface of a flexible substrate facing the first chromium target and the second chromium target.

In accordance with such a deposition method, the chromium layer is formed on the deposition surface of the flexible substrate in the state in which the water partial pressure inside the vacuum chamber is at the desired value or less. With this, reaction between the chromium layer and water is suppressed and a chromium oxide is not easily formed inside the chromium layer. In addition, the chromium layer is formed by the plasma generated by applying the AC voltage between the first chromium target and the second chromium target. With this, sputtered particles easily enter the flexible substrate in more random directions. As a result, deformation of the flexible substrate on which the chromium layer is formed is suppressed as much as possible.

In the above-mentioned deposition method, the desired value may be 3.0×10⁻⁴ Pa and the water partial pressure may be set to 3.0×10⁻⁴ Pa or less.

With this, the chromium layer is formed on the deposition surface of the flexible substrate in the state in which the water partial pressure inside the vacuum chamber is at 3.0×10⁻⁴ Pa or less, and deformation of the flexible substrate on which the chromium layer is formed is suppressed as much as possible.

In the above-mentioned deposition method, in the pre-treatment, the flexible substrate may be heated to be at 60° C. or more and 180° C. or less.

With this, the flexible substrate is heated to be at 60° C. or more and 180° C. or less as the pre-treatment and even in a case where the chromium layer is formed on the deposition surface of the flexible substrate, deformation of the flexible substrate is suppressed as much as possible.

In the above-mentioned deposition method, in the pre-treatment, pre-discharge may be performed by applying the AC voltage between the first chromium target and the second chromium target.

With this, the pre-discharge is performed between the first chromium target and the second chromium target as the pre-treatment and even in a case where the chromium layer is formed on the deposition surface of the flexible substrate, deformation of the flexible substrate is suppressed as much as possible.

In the above-mentioned deposition method, in the step of forming the chromium layer, a frequency of 10 kHz or more and 100 kHz or less may be used as a frequency of the AC voltage.

With this, in the step of forming the chromium layer, the frequency of 10 kHz or more and 100 kHz or less is used as the frequency of the AC voltage, and even in a case where the chromium layer is formed on the deposition surface of the flexible substrate, deformation of the flexible substrate is suppressed as much as possible.

In the above-mentioned deposition method, in the step of forming the chromium layer, AC power of 1.0 W/cm² or more and 3.0 W/cm² or less may be input into the first chromium target or the second chromium target.

With this, in the step of forming the chromium layer, AC power of 1.0 W/cm² or more and 3.0 W/cm² or less is input into the first chromium target and the second chromium target, and even in a case where the chromium layer is formed on the deposition surface of the flexible substrate, deformation of the flexible substrate is suppressed as much as possible.

In the above-mentioned deposition method, a target surface of the first chromium target may be disposed in parallel with a target surface of the second chromium target.

With this, in the step of forming the chromium layer, an incident angle of sputtered particles, which is incident to the deposition surface of the flexible substrate, is wider, and even in a case where the chromium layer is formed on the deposition surface of the flexible substrate, deformation of the flexible substrate is suppressed as much as possible.

In the above-mentioned deposition method, a polyimide film may be used as the flexible substrate.

With this, the polyimide film is used as the flexible substrate, and even in a case where the chromium layer is formed on the deposition surface of the polyimide film, deformation of the polyimide film is suppressed as much as possible.

In order to accomplish the above-mentioned object, a roll-to-roll deposition apparatus according to an embodiment of the present invention includes a vacuum chamber, an exhaust mechanism, a film-transferring mechanism, and a deposition source. The vacuum chamber is capable of maintaining a reduced pressure state. The exhaust mechanism is capable of exhausting the vacuum chamber until a water partial pressure inside the vacuum chamber becomes equal to or lower than a desired value. The film-transferring mechanism is capable of causing a flexible substrate to transfer inside the vacuum chamber. The deposition source includes a first chromium target and a second chromium target, the first chromium target and the second chromium target facing a deposition surface of the flexible substrate and being disposed along a transfer direction of the flexible substrate. The deposition source is capable of generating plasma by applying an AC voltage between the first chromium target and the second chromium target and forming a chromium layer on the deposition surface.

In accordance with such a roll-to-roll deposition apparatus, the chromium layer is formed on the deposition surface of the flexible substrate in the state in which the water partial pressure inside the vacuum chamber is at the desired value or less. With this, reaction between the chromium layer and water is suppressed and a chromium oxide is not easily formed inside the chromium layer. In addition, the chromium layer is formed by the plasma generated by applying the AC voltage between the first chromium target and the second chromium target. With this, sputtered particles easily enter the flexible substrate in more random directions. As a result, deformation of the flexible substrate on which the chromium layer is formed is suppressed as much as possible.

### ADVANTAGEOUS EFFECTS OF INVENTION

As described above, in accordance with the present invention, deformation of the flexible substrate is suppressed even in a case where a chromium layer is formed on a flexible substrate.

### BRIEF DESCRIPTION OF DRAWINGS

FIG. 1 A schematic block configuration diagram of a deposition apparatus according to a first embodiment.

FIG. 2 A schematic configuration diagram of the deposition apparatus according to the first embodiment.

FIG. 3 A flowchart showing a deposition method according to this embodiment.

FIGS. 4A and 4B are schematic cross-sectional views showing an example of the deposition method according to this embodiment.

FIG. 5A is a schematic graph diagram showing a relationship between a heating temperature of a flexible substrate and compressive stress of a chromium layer. FIG. 5B is a schematic graph diagram showing a relationship between a pre-discharge time and the compressive stress of the chromium layer. FIG. 5C is a schematic graph diagram showing a relationship between the pre-treatment time and the compressive stress of the chromium layer.

FIG. 6A is a schematic graph diagram showing a relationship between a frequency band of an AC voltage and the compressive stress of the chromium layer. FIG. 6B is a schematic graph diagram showing a relationship between MF power and the compressive stress of the chromium layer.

FIG. 7A is a schematic cross-sectional view showing a state in which a flexible substrate on which a chromium layer is formed is warped and FIGS. 7B to 7D are a diagram and tables showing an amount of warp of the flexible substrate on which the chromium layer is formed.

FIGS. 8A and 8B are schematic configuration diagrams of a deposition apparatus according to a second embodiment.

### MODE(S) FOR CARRYING OUT THE INVENTION

Hereinafter, embodiments of the present invention will be described with reference to the drawings. In some of the drawings, XYZ-axis coordinates are introduced.

### FIRST EMBODIMENT

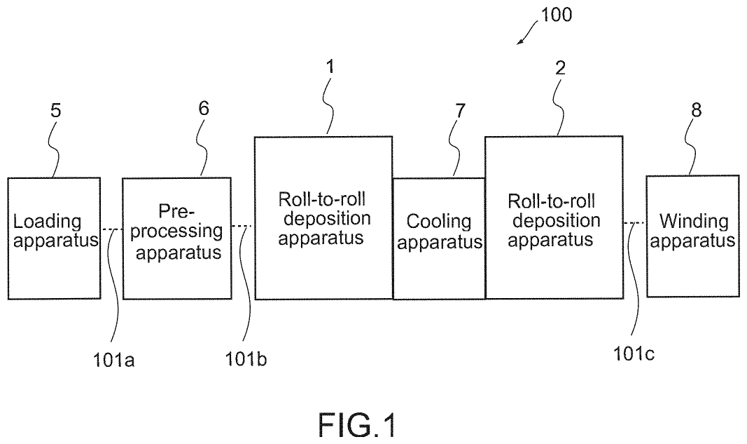

FIG. 1 is a schematic block configuration diagram of a deposition apparatus according to a first embodiment.

As shown in FIG. 1, a deposition apparatus 100 according to this embodiment includes a loading apparatus 5, a pre-processing apparatus 6, a roll-to-roll deposition apparatus 1, a cooling apparatus 7, a roll-to-roll deposition apparatus 2, and a winding apparatus 8. The loading apparatus 5 is connected to the pre-processing apparatus 6 via a connecting channel 101a. The pre-processing apparatus 6 is connected to the roll-to-roll deposition apparatus 1 via a connecting channel 101b. The roll-to-roll deposition apparatus 2 is connected to the winding apparatus 8 via a connecting channel 101c. The roll-to-roll deposition apparatus 1 is connected to the roll-to-roll deposition apparatus 2 via the cooling apparatus 7. Each of the loading apparatus 5, the pre-processing apparatus 6, the roll-to-roll deposition apparatus 1, the roll-to-roll deposition apparatus 2, and the winding apparatus 8 is provided with an evacuation mechanism.

The respective apparatuses constituting the deposition apparatus 100 are arranged in the order along a direction (in FIG. 1, a left-to-right direction) in which a flexible substrate (e.g., a resin film) which is an object to be processed is transferred. For example, the flexible substrate which is the object to be processed is placed inside the loading apparatus 5 in advance. The flexible substrate transferred from the loading apparatus 5 to the pre-processing apparatus 6 is subjected to pre-processing inside the pre-processing apparatus 6. The flexible substrate transferred from the pre-processing apparatus 6 to the roll-to-roll deposition apparatus 1 is subjected to deposition treatment inside the roll-to-roll deposition apparatus 1. The flexible substrate transferred from the roll-to-roll deposition apparatus 1 to the cooling apparatus 7 is made cooled inside the cooling apparatus 7. The flexible substrate transferred from the cooling apparatus 7 to the roll-to-roll deposition apparatus 2 is subjected to deposition treatment inside the roll-to-roll deposition apparatus 2. Then, the flexible substrate transferred from the roll-to-roll deposition apparatus 2 to the winding apparatus 8 is wound inside the winding apparatus 8.

Hereinafter, a configuration of the roll-to-roll deposition apparatus 1 in the deposition apparatus 100 will be described in detail.

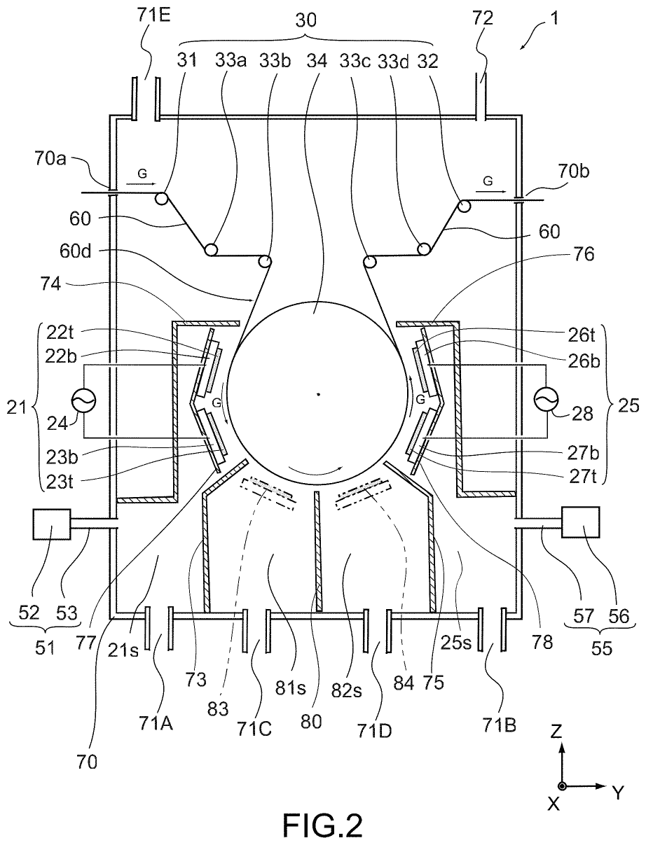

FIG. 2 is a schematic configuration diagram of the deposition apparatus according to the first embodiment.

FIG. 2 shows the roll-to-roll deposition apparatus 1 in the deposition apparatus 100. The above-mentioned connecting channel 101b is connected to the left of the roll-to-roll deposition apparatus 1. Further, the above-mentioned cooling apparatus 7 is connected to the right of the roll-to-roll deposition apparatus 1. In FIG. 2, the connecting channel 101b and the cooling apparatus 7 are not shown.

The roll-to-roll deposition apparatus 1 shown in FIG. 2 is a deposition apparatus capable of forming a film (e.g., a chromium layer) on the flexible substrate 60 (e.g., a resin film such as a polyimide film) while causing a flexible substrate 60 to transfer inside the vacuum chamber 70. The flexible substrate 60 on which the chromium layer is formed is applied to a flexible sensor substrate, a flexible printed circuit board, and the like, for example.

The roll-to-roll deposition apparatus 1 includes deposition sources 21 and 25, a film-transferring mechanism 30, water partial pressure detecting mechanisms 51 and 55, a vacuum chamber 70, and exhaust lines 71A, 71B, 71C, 71D, and 71E.

In addition, the roll-to-roll deposition apparatus 1 includes a gas supply line 72, adhesion preventing plates (or partition members) 73, 74, 75, 76, and 80, and supports 77 and 78.

First of all, the film-transferring mechanism 30 will be described. The film-transferring mechanism 30 is capable of causing the flexible substrate 60 to transfer inside the vacuum chamber 70. The film-transferring mechanism 30 includes a guide roller 31, a guide roller 32, guide rollers 33a, 33b, 33c, and 33d, and a main roller 34. Each of the guide roller 31, the guide roller 32, the guide rollers 33a, 33b, 33c, and 33d, and the main roller 34 has a tubular shape. A rotational drive mechanism that rotationally drives the main roller 34 is provided outside the roll-to-roll deposition apparatus 1.

The flexible substrate 60 is a long film cut in a predetermined width. The back surface of the flexible substrate 60 (surface opposite to a deposition surface 60d) is held in contact with a roller surface of the main roller 34 at a deposition position. The flexible substrate 60 is continuously carried into the roll-to-roll deposition apparatus 1 through an inlet 70a of the vacuum chamber 70. In the example of FIG. 2, a transfer direction of the flexible substrate 60 inside the vacuum chamber 70 is shown as arrows G, for example.

In addition, the flexible substrate 60 is guided to the roller surface of the main roller 34 by the guide rollers 31, 33a, and 33b. The flexible substrate 60 on the main roller 34, which is guided to the main roller 34, is further guided by the guide rollers 33c, 33d, and 32. Then, the flexible substrate 60 is carried outside from the roll-to-roll deposition apparatus 1 through an outlet 70b of the vacuum chamber 70.

It should be noted that in the roll-to-roll deposition apparatus 1, each of the guide rollers 33a, 33b, 33c, and 33d and the main roller 34 can also be inversely rotated. With this, the flexible substrate 60 can also be transferred in a direction opposite to the arrows G.

A temperature control mechanism such as a temperature control medium circulation system may be provided inside the main roller 34. With this temperature control mechanism, the temperature of the flexible substrate 60 in contact with the main roller 34 is adjusted as appropriate, for example. For example, when plasma is generated by the deposition sources 21 and 25 inside the vacuum chamber 70, there is a possibility that the temperature of the flexible substrate 60 excessively increases due to this plasma.

In this case, the temperature of the flexible substrate 60 is adjusted as appropriate by the temperature control mechanism so as to prevent the temperature of the flexible substrate 60 from excessively increasing. In addition, degassing treatment and dewatering treatment for the flexible substrate 60 can be performed by increasing the temperature of the main roller 34 by a degree that the flexible substrate 60 is not deformed (e.g., 60° C. or more and 180° C. or less) without generating plasma and causing the flexible substrate 60 to transfer inside the vacuum chamber 70.

Next, a deposition source 21 and a deposition source 25 will be described. The deposition source 21 and the deposition source 25 are so-called dual cathode sputter sources. One of the deposition source 21 and the deposition source 25 may be omitted in a manner that depends on needs. Herein, the roll-to-roll deposition apparatus 1 including the deposition source 21 and the deposition source 25 will be described as an example. In the roll-to-roll deposition apparatus 1, the deposition source 21 and the deposition source 25 are disposed so as to be opposed to each other, sandwiching the main roller 34, for example. For example, in the example of FIG. 2, the deposition source 21, the main roller 34, and the deposition source 25 are arranged in the order in a Y-axis direction.

Further, one of the deposition source 21 and the deposition source 25 may be a plasma generating source for non-deposition, not the dual cathode sputter source, or may be a direct current (DC) sputter source or RF sputter source including a target other than the chromium target. In this case, pre-processing (plasma cleaning) is performed on the flexible substrate 60, removal of electricity for the flexible substrate 60 is performed, and a layer other than the chromium layer is formed on the flexible substrate 60 by either one of the deposition source 21 or the deposition source 25.

The deposition source 21 includes a chromium target 22t, a backing plate 22b, a chromium target 23t, a backing plate 23b, and an alternate current (AC) power supply 24. The AC power supply 24 is capable of applying an AC voltage between the chromium target 22t and the chromium target 23t. The deposition source 21 may be a magnetron sputter source including magnets disposed inside the backing plate 22b and the backing plate 23b. A cooling mechanism may be provided inside each of the backing plate 22b and the backing plate 23b.

Each of the chromium target 22t and the chromium target 23t faces the deposition surface 60d of the flexible substrate 60. For example, the chromium target 22t and the chromium target 23t are arranged along the transfer direction (arrows G) of the flexible substrate 60. For example, in the example of FIG. 2, the chromium target 22t and the chromium target 23t are arranged to be aligned in a Z-axis direction.

For example, a support 77 that supports the chromium target 22t and the chromium target 23t are bent forming an obtuse angle between the chromium target 22t and the chromium target 23t. With this, the chromium target 22t and the chromium target 23t are respectively disposed such that the respective target surfaces are directed to the center of the main roller 34 via the flexible substrate 60.

When an AC voltage is applied between the chromium target 22t and the chromium target 23t, plasma (e.g., Ar plasma) is generated inside the vacuum chamber 70. With this, sputtered particles are floating toward the deposition surface 60d of the flexible substrate 60 from each of the chromium target 22t and the chromium target 23t. A chromium layer is thus formed on the deposition surface 60d of the flexible substrate 60

The deposition source 25 includes a chromium target 26t, a backing plate 26b, a chromium target 27t, a backing plate 27b, and an AC power supply 28. The AC power supply 28 is capable of applying an AC voltage between the chromium target 26t and the chromium target 27t. The deposition source 25 may be a magnetron sputter source including magnets disposed inside the backing plate 26b and the backing plate 27b. A cooling mechanism may be provided inside each of the backing plate 26b and the backing plate 27b.

Each of the chromium target 26t and the chromium target 27t faces the deposition surface 60d of the flexible substrate 60. For example, the chromium target 26t and the chromium target 27t are arranged to be aligned along the transfer direction (arrows G) of the flexible substrate 60. For example, in the example of FIG. 2, the chromium target 26t and the chromium target 27t are arranged to be aligned in the Z-axis direction.

A support 78 that supports the chromium target 26t and the chromium target 27t is bent forming an obtuse angle between the chromium target 26t and the chromium target 27t. With this, the chromium target 26t and the chromium target 27t are respectively disposed such that the respective target surfaces are directed to the center of the main roller 34 via the flexible substrate 60.

When an AC voltage is applied between the chromium target 26t and the chromium target 27t, plasma (e.g., Ar plasma) is generated inside the vacuum chamber 70. With this, sputtered particles are floating toward the deposition surface 60d of the flexible substrate 60 from each of the chromium target 26t and the chromium target 27t. A chromium layer is thus formed on the deposition surface 60d of the flexible substrate 60.

In this embodiment, the chromium layer is formed in such a manner that a water partial pressure inside the vacuum chamber 70 is adjusted to a pressure equal to or lower than a desired value. For example, the chromium layer is formed on the flexible substrate 60 in such a manner that a water partial pressure in a space in which the deposition sources 21 and 25 and the main roller 34 face each other is adjusted to a partial pressure equal to or lower than the desired value. Here, a space 21s is a space surrounded by the main roller 34, an adhesion preventing plate 73, an adhesion preventing plate 74, and the support 77, for example. Further, the space 25s is a space surrounded by the main roller 34, an adhesion preventing plate 75, an adhesion preventing plate 76, and the support 78, for example. The desired value of the water partial pressure is, for example, 3.0×10⁻⁴ Pa, and the water partial pressure is set to 3.0×10⁻⁴ Pa or less.

A frequency of an AC voltage to be supplied to the chromium target 22t and the chromium target 23t or a frequency of an AC voltage to be supplied to the chromium target 26t and the chromium target 27t by the AC power supply 24 is 10 kHz or more and 100 kHz or less, for example. Hereinafter, this frequency band will be referred to as a middle frequency (MF). Further, AC discharge based on the MF will be referred to as MF discharge. The discharge power based on the MF will be referred to as MF power. A discharge method of producing the MF discharge between the two targets will be referred to as dual-type MF discharge. It should be noted that an AC voltage waveform includes rectangle waves as well as a sine waveform.

Further, when the chromium layer is formed on the deposition surface 60d of the flexible substrate 60, the AC power supply 24 supplies power of 1.0 kW or more 3.0 kW or less between the chromium targets 22t and 23t and the AC power supply 28 supplies power of 1.0 kW or more 3.0 kW or less between the chromium targets 26t and 27t. At this time, AC power of 1.0 W/cm² or more and 3.0 W/cm² or less, for example, is input into each of the chromium target 22t, the chromium target 23t, the chromium target 26t, and the chromium target 27t.

The deposition sources 21 and 25, the film-transferring mechanism 30, the adhesion preventing plates 73, 74, 75, 76, 80, and the supports 77 and 78, and the flexible substrate 60 described above are housed in the vacuum chamber 70. The vacuum chamber 70 is capable of maintaining a reduced pressure state. For example, the inside of the vacuum chamber 70 is maintained at a predetermined degree of vacuum through exhaust lines 71A, 71B, 71C, 71D, 71D, and 71E connected to a vacuum pumping system (not shown) such as a vacuum pump. The vacuum chamber 70 is exhausted via the exhaust lines 71A, 71B, 71C, 71D, 71D, and 71E until the water partial pressure inside the vacuum chamber 70 becomes equal to or lower than the desired value (3.0×10⁻⁴ Pa). The exhaust lines 71A, 71B, 71C, 71D, 71D, and 71E may be respectively independently connected to different vacuum pumping systems or at least two of the exhaust lines 71A, 71B, 71C, 71D, 71D, and 71E may be connected to the same vacuum pumping system.

For example, a space surrounded by the adhesion preventing plate 74, the main roller 34, and the adhesion preventing plate 76 inside the vacuum chamber 70 is exhausted via the exhaust line 71E. The above-mentioned space 21s is exhausted via the exhaust line 71A. The space 25s is exhausted via the exhaust line 71B. Further, in the roll-to-roll deposition apparatus 1, a space 81s surrounded by the adhesion preventing plates 73, the main roller 34, and the adhesion preventing plate 80 is formed inside the vacuum chamber 70 as well as the above-mentioned space. The space 81s is exhausted via the exhaust line 71C. Further, a space 82s surrounded by the adhesion preventing plate 75, the main roller 34, and the adhesion preventing plate 80 is formed inside the vacuum chamber 70. The space 82s is exhausted via the exhaust line 71D.

In the roll-to-roll deposition apparatus 1, a target 83 can also be placed in the space 81s. Further, a target 84 can also be placed in the space 82s. FIG. 2 shows a state in which the targets 83 and 84 are removed. Further, each of the targets 83 and 84 may be a single cathode or may be a dual cathode. The material of each of the targets 83 and 84 may be a material other than chromium.

In addition, gas for discharge such as inert gas (Ar, He, etc.) is supplied into the vacuum chamber 70 at a predetermined flow rate via the gas supply line 72 connected to a gas source (not shown) such as a gas cylinder.

The water partial pressure detecting mechanism 51 includes a gas monitor 52 and a pipe 53. The gas monitor 52 typically includes a mass spectrometer. The pipe 53 is provided with an orifice therein. By performing differential evacuation on the gas monitor 52 through the pipe 53, the water partial pressure in the space 21s is measured. Similarly, the water partial pressure detecting mechanism 55 includes a gas monitor 56 and a pipe 57. The gas monitor 56 typically includes a mass spectrometer. The pipe 57 is provided with an orifice therein. By performing differential evacuation on the gas monitor 56 through the pipe 57, the water partial pressure in the space 25s is measured.

In accordance with the above-mentioned roll-to-roll deposition apparatus 1, the chromium layer is formed on the deposition surface 60d of the flexible substrate 60 in a state in which the water partial pressure inside the vacuum chamber 70 is equal to or lower than the desired value. With this, even in a case where the chromium layer is formed on the flexible substrate 60, the stress of the chromium layer is reduced as appropriate in accordance with a deposition condition, and deformation of the flexible substrate 60 is suppressed as much as possible. Here, the stress is compressive stress of the chromium layer. Further, the deformation is a curl or the like of the flexible substrate 60 in a direction perpendicular to the transfer direction G, for example.

Further, in the deposition apparatus 100 (FIG. 1), the basic configuration of the roll-to-roll deposition apparatus 2 may be the same as the roll-to-roll deposition apparatus 1. The target material of the roll-to-roll deposition apparatus 2 may be different from the target material of the roll-to-roll deposition apparatus 1.

### Deposition Method

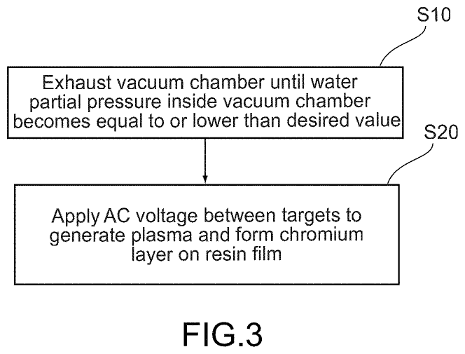

FIG. 3 is a flowchart showing a deposition method according to this embodiment.

In the deposition method according to this embodiment, for example, pre-treatment in which the vacuum chamber 70 is exhausted until the water partial pressure inside the vacuum chamber 70 becomes equal to or lower than the desired value is performed (Step S10).

Next, by applying an AC voltage between the chromium target 22t and the chromium target 23t (or between the chromium target 26t and the chromium target 27t), which are disposed inside the vacuum chamber 70, plasma is generated and a chromium layer is formed on the deposition surface 60d of the flexible substrate 60 made facing the chromium targets 22t and 23t (or the chromium targets 26t and 27t) (Step S20).

For example, if a trace amount of water vapor is present inside the vacuum chamber 70, sputtered particles of the chromium react with the water vapor and a chromium layer including a trace amount of chromium oxide may be formed on the flexible substrate 60. In contrast, in this embodiment, the chromium layer is formed on the deposition surface 60d of the flexible substrate 60 in a state in which the water partial pressure inside the vacuum chamber 70 is equal to or lower than the desired value. With this, reaction between the chromium layer and water is suppressed and a chromium oxide is not easily formed inside the chromium layer. In addition, the chromium layer is formed by the plasma generated by applying the AC voltage between the chromium target 22t and the chromium target 23t (or between the chromium target 26t and the chromium target 27t). With this, sputtered particles easily enter the flexible substrate 60 in more random directions. As a result, even in a case where the chromium layer is formed on the flexible substrate 60, the stress of the chromium layer is reduced as appropriate in accordance with a deposition condition, and deformation of the flexible substrate 60 is suppressed as much as possible.

Next, a specific example of the deposition method (deposition condition) according to this embodiment will be described. In deposition according to this embodiment, the roll-to-roll deposition apparatus 1 shown in FIG. 2 is used as an example.

First of all, pre-treatment of exhausting the vacuum chamber 70 is performed before the chromium layer is formed on the flexible substrate 60. In this pre-treatment, the exhaustion of the vacuum chamber 70 is performed until the water partial pressures of the spaces 21s and 25s inside the vacuum chamber 70 become equal to or lower than the desired value.

Positions at which water easily outgases when the vacuum chamber 70 is exhausted are inner walls of the vacuum chamber 70, the flexible substrate 60, and the deposition sources 21 and 25, and the like, for example. First of all, the vacuum chamber 70 is exhausted via the exhaust lines 71A, 71B, 71C, 71D, 71D, and 71E in advance. This preliminary exhaustion time is not particularly limited and is, for example, 1 hour or more and 2 hours or less.

Next, dewatering treatment of the flexible substrate 60 is performed while the vacuum chamber 70 is exhausted via the exhaust lines 71A, 71B, 71C, 71D, 71D, and 71E. For example, the temperature of the main roller 34 is adjusted to 60° C. or more and 180° C. or less and the film-transferring mechanism 30 causes the flexible substrate 60 to transfer inside the vacuum chamber 70. For example, the temperature of the main roller 34 is set to 150° C. in advance. Next, the flexible substrate 60 is carried into the vacuum chamber 70 through the inlet 70a of the vacuum chamber 70, and the flexible substrate 60 is carried out from an outlet 7b of the vacuum chamber 70 while the flexible substrate 60 is held in contact with the main roller 34. After that, the flexible substrate 60 is wound inside the winding apparatus 8. In this dewatering treatment, a winding time (heating time of the flexible substrate 60) in which the flexible substrate 60 payed out from the loading apparatus 5 is wound by the winding apparatus 8 is not particularly limited and is, for example, one minute or more and three minutes or less (e.g., two minutes).

With this, water outgases efficiently from the flexible substrate 60. It should be noted that it is unfavorable because water does not easily outgas from the flexible substrate 60 when the temperature of the main roller 34 becomes lower than 60° C. On the other hand, it is unfavorable because the flexible substrate 60 itself may change in quality when the temperature of the main roller 34 becomes higher than 180° C.

In addition, in this embodiment, pre-discharge in which plasma is generated inside the vacuum chamber 70 is performed while the vacuum chamber 70 is exhausted via the exhaust lines 71A, 71B, 71C, 71D, 71D, and 71E. For example, an AC voltage is applied between the chromium target 22t and the chromium target 23t or between the chromium target 26t and the chromium target 27t and plasma is generated inside the vacuum chamber 70. The dual-type MF discharge, for example, is employed in this pre-discharge.

With this pre-discharge, peripheries of the deposition sources 21 and 25 are heated by the plasma, and the water efficiently outgases from the peripheries of the deposition sources 21 and 25. For example, Ar gas is used as discharge gas. A pressure of the Ar gas is adjusted to 0.1 Pa or more and 1 Pa or less, for example. A frequency of an AC voltage is adjusted to 10 kHz or more and 100 kHz or less, for example. Further, AC power of 1.0 W/cm² or more and 3.0 W/cm² or less, for example, is input into each of the chromium target 22t, the chromium target 23t, the chromium target 26t, and the chromium target 27t. The pre-discharge is performed for 30 minutes or more, for example.

A pre-treatment time including the preliminary exhaustion, the heating of the flexible substrate 60, and the pre-discharge as described above is not particularly limited and is 2 hours or more and 6 hours or less, for example. It should be noted that the heating of the flexible substrate 60 and the pre-discharge may be performed at the same time. Further, at least either one of the heating of the flexible substrate 60 or the pre-discharge may be performed during the preliminary exhaustion.

With the above-mentioned pre-treatment, the water partial pressures of the spaces 21s and 25s inside the vacuum chamber 70 are adjusted to be 3.0×10⁻⁴ Pa or less. It should be noted that a total pressure (ultimate pressure) inside the vacuum chamber 70 when the water partial pressure becomes 3.0×10⁻⁴ Pa or less is 3.0×10⁴ Pa or less, for example.

With this, a chromium layer having reduced compressive stress is formed on the flexible substrate 60. For example, when the water partial pressure becomes higher than 3.0×10⁻⁴ Pa, a trace amount of chromium oxide is easily contained in the chromium layer and the compressive stress of the chromium layer increases.

Further, in this embodiment, the compressive stress of the chromium layer is made more suitable by adjusting discharge frequencies and discharge power of the deposition sources 21 and 25 as well as the water partial pressure inside the vacuum chamber 70.

Here, means for forming a chromium layer on the flexible substrate 60 includes a pulsed DC sputtering method or an RF sputtering method.

In the pulsed DC sputtering method, the flexible substrate 60 is made facing the chromium target, a pulse DC voltage is applied on this chromium target, and a chromium layer is formed on the flexible substrate 60.

In the pulsed DC sputtering method, the discharge happens between the chromium target and the main roller 34 due to a direct-current voltage via the flexible substrate 60. With this discharge, sputtered particles advance toward the flexible substrate 60 from the chromium target and a chromium layer having a predetermined thickness is deposited on the flexible substrate 60. However, in the pulsed DC sputtering method, sputtered particles easily advance straight toward the flexible substrate 60 from the chromium target because a DC bias voltage is applied between the chromium target and the main roller 34.

With this, the chromium layer tends to be a layer formed by deposition of sputtered particles accelerated in a particular direction (direction from the chromium target to the flexible substrate 60) mainly due to a DC voltage. As a result, the chromium layer becomes dense, orientations of crystals are easily aligned in one direction, and the compressive stress of the chromium layer is relatively high.

On the other hand, in the RF sputtering method, the chromium target is made facing the flexible substrate 60, an RF voltage is applied on this chromium target, and a chromium layer is formed on the flexible substrate 60.

In the RF sputtering method, the frequency is several tens of MHz (e.g., 13.56 MHz) and sputtered particles in the plasma cannot follow modulations of the RF frequency. With this, the chromium layer on the flexible substrate 60 becomes a layer formed by deposition of sputtered particles accelerated mainly due to self-bias, and easily becomes a dense layer whose orientations of crystals are aligned in one direction. In addition, the plasma density (electron density) in the RF discharge is relatively high and chromium in the plasma is more active. With this, chromium is liable to react with a trace amount of water and oxygen in the plasma and a trace amount of chromium oxide is easily contained in the chromium layer. As a result, also in the chromium layer formed by the RF sputtering method, the compressive stress thereof becomes high.

For example, in general, the electron density based on the DC discharge is 1×10⁷ (cm⁻³) or more and 1'10¹⁰ (cm⁻³) or less while the electron density based on the RF discharge is 5×10⁷ (cm⁻³) or more and 5×10¹¹ (cm⁻³) or less. Further, in the RF discharge, the electron density tends to become higher as the frequency becomes higher. In this manner, in the RF discharge, the plasma density is higher and the reactivity is higher.

It should be noted that in the pulsed DC sputtering method and the RF sputtering method, even in a case where the two targets are prepared and power is input into each of these two targets, the compressive stress of the chromium layer similarly increases because the two targets are simply arranged to be aligned.

In contrast, in this embodiment, the MF AC voltage is applied between the two targets, and the chromium layer is formed on the flexible substrate 60 by the MF discharge generated between the targets.

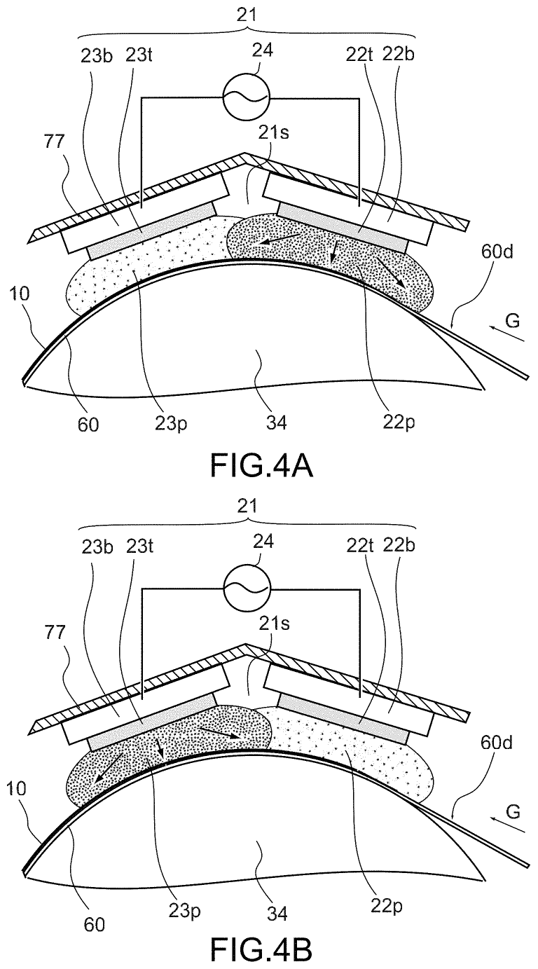

FIGS. 4A and 4B are schematic cross-sectional views showing an example of the deposition method according to this embodiment.

In FIGS. 4A and 4B, a periphery of the deposition source 21 is shown as an example. The same actions as the deposition source 21 are provided also in the deposition source 25.

For example, after the water partial pressure inside the vacuum chamber 70 (space 21s) is adjusted to be 3.0×10⁻⁴ Pa or less, Ar gas is introduced into the vacuum chamber 70 (space 21s) via the gas supply line 72. A pressure of the Ar gas is 0.1 Pa or more and 1 Pa or less, for example.

Next, an AC voltage is applied between the chromium target 22t and the chromium target 23t and plasma 22p and 23p is formed in the space 21s. A frequency of 10 kHz or more and 100 kHz or less (e.g., 35 kHz) is used as a frequency of an AC voltage, for example.

The MF AC voltage is applied between the chromium targets 22t and 23t. Therefore, a time for which a peak voltage of an AC voltage is input into the chromium target 22t and a time for which a peak voltage of an AC voltage is input into the chromium target 22t are periodically repeated. With this, a time (FIG. 4A) for which the plasma 22p is preferentially generated near the chromium target 22t and a time (FIG. 4B) for which the plasma 23p is preferentially generated near the chromium target 23t are periodically repeated. For example, when the MF is 35 kHz, the state of FIG. 4A and the state of FIG. 4B are alternately obtained 35000 times in one second. It should be noted that in FIG. 4A and FIG. 4B, a state having a higher plasma density is shown as a dark dotted pattern and a state having a lower plasma density is shown as a light dotted pattern.

With this, sputtered particles emitted from the chromium target 22t and sputtered particles emitted from the chromium target 23t alternately enter the flexible substrate 60 wound around the main roller 34. That is, the direction of an electric field directed to the flexible substrate 60 from the sputtering target periodically changes. As a result, in the flexible substrate 60 facing the deposition source 21, sputtered particles easily enter the flexible substrate 60 in more random directions in comparison with the pulsed DC sputtering method and the RF sputtering method (in the figure, arrows). With this, in this embodiment, the orientations of crystals of the chromium layer become more random. A chromium layer having reduced internal stress, i.e., a chromium layer 10 having reduced compressive stress in comparison with the DC sputtering method and the RF sputtering method is formed on the flexible substrate 60. It should be noted that a thickness of the chromium layer 10 is, for example, 100 nm to 300 nm and is, for example, 200 nm.

Further, the MF frequency is lower than the RF frequency. With this, the plasma density of the plasma 22p and 23p is lower than the plasma density of the plasma based on the RF discharge. With this, in the plasma 22p and 23p, chromium activation is suppressed in comparison with the RF discharge. As a result, chromium does not easily react with water and the chromium oxide is not easily contained in the chromium layer 10.

In addition, in this embodiment, power of 1.0 kW or more and 3.0 kW or less is supplied as the MF discharge power between the chromium targets 22t and 23t, for example. With this, MF power of 1.0 W/cm² or more and 3.0 W/cm² or less is input into each of the chromium target 22t and the chromium target 23t, for example. Here, it is unfavorable because the deposition rate of the chromium layer 10 is extremely lowered if the MF power is lower than 1.0 W/cm². On the other hand, it is unfavorable because chromium activation is promoted in the plasma 22p and 23p and the chromium oxide is easily contained in the chromium layer 10 if the MF power is higher than 3.0 W/cm².

Relationships between respective parameters of the deposition condition in the above-mentioned deposition method and the compressive stress of the chromium layer 10 are summarized as follows.

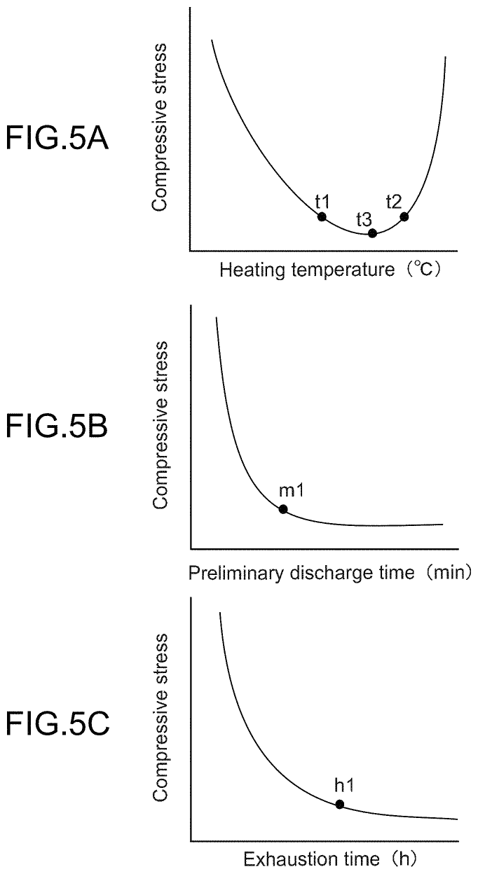

FIG. 5A is a schematic graph diagram showing a relationship between a heating temperature of the flexible substrate and the compressive stress of the chromium layer. FIG. 5B is a schematic graph diagram showing a relationship between a pre-discharge time and the compressive stress of the chromium layer. FIG. 5C is a schematic graph diagram showing a relationship between a pre-treatment time and the compressive stress of the chromium layer. The vertical axes of FIGS. 5A to 5C show standard values of the compressive stress of the chromium layer.

In the pre-treatment, as shown in FIG. 5A, it is favorable that the flexible substrate 60 is heated at a temperature in a range of t1 (° C.) or more and t2 (° C.) or less. Here, t1 is 60° C., for example, and t2 is 180° C., for example. In this temperature range, the compressive stress of the chromium layer 10 is sufficiently reduced. It should be noted that a temperature t3 at which the compressive stress of the chromium layer 10 is extremely small is 150° C., for example.

Further, in the pre-treatment, it is favorable that the pre-discharge is performed for m1 minutes or more as shown in FIG. 5B. Here, m1 is 30 minutes, for example. The compressive stress of the chromium layer 10 is sufficiently reduced by pre-discharge for 30 minutes or more.

Further, it is favorable that the pre-treatment including the heating treatment and the pre-discharge is performed for h1 hours or more as shown in FIG. 5C. Here, h1 is two hours, for example. The compressive stress of the chromium layer 10 is sufficiently reduced by pre-treatment for two hours or more.

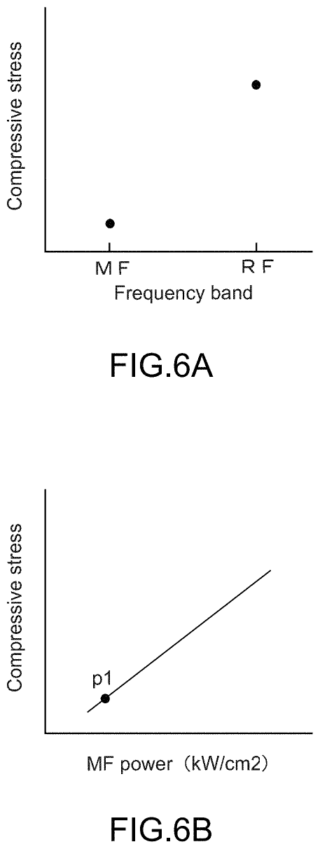

FIG. 6A is a schematic graph diagram showing a relationship between a frequency band of an AC voltage and the compressive stress of the chromium layer. FIG. 6B is a schematic graph diagram showing a relationship between the MF power and the compressive stress of the chromium layer. The vertical axes of FIGS. 6A and 6B are standard values of the compressive stress of the chromium layer.

As shown in FIG. 6A, in this embodiment, in order to sufficiently reduce the compressive stress of the chromium layer 10, the MF, not the RF, is employed as the frequency of the AC voltage. Here, the MF is 10 kHz or more and 100 kHz or less, for example.

As shown in FIG. 6B, in this embodiment, in order to sufficiently reduce the compressive stress of the chromium layer 10, the MF power is adjusted to be p1 (W/cm²) or less. Here, p1 is 1.0 W/cm² or more and 3.0 W/cm² or less, for example.

### Evaluation of Chromium Layer

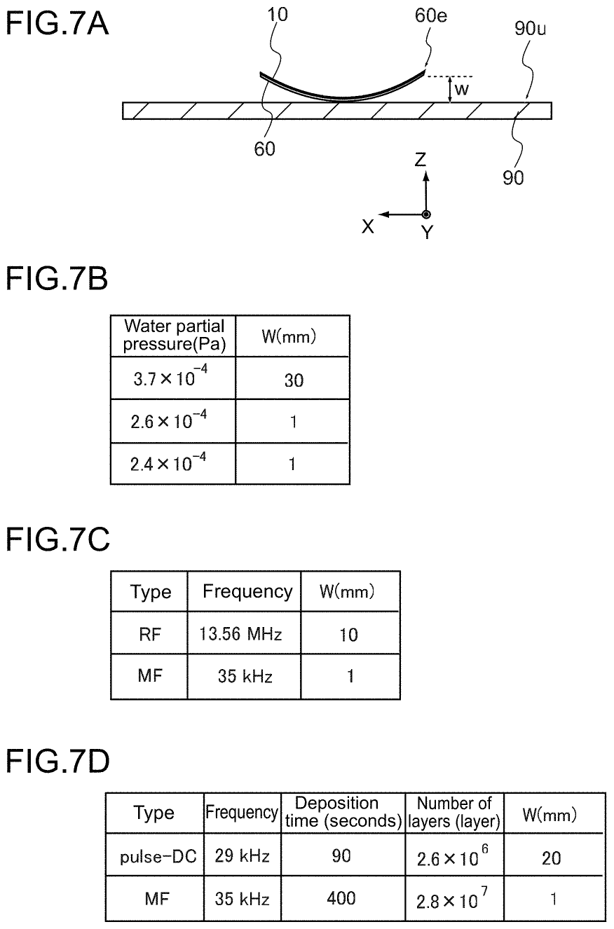

FIG. 7A is a schematic cross-sectional view showing a state in which a flexible substrate on which a chromium layer is formed is warped. FIGS. 7B to 7D are a diagram and tables showing an amount of warp of the flexible substrate on which the chromium layer is formed. It should be noted that the thickness of the chromium layer 10 is 200 nm, for example.

As shown in FIG. 7A, when the chromium layer 10 having predetermined compressive stress is formed on the flexible substrate 60, the flexible substrate 60 is warped as a protrusion toward an underlayer 90 on which the flexible substrate 60 is placed. This warp is so-called curling. Here, the X-axis direction in FIG. 7A corresponds to a width direction of the flexible substrate 60 and the Y-axis direction corresponds to the transfer direction of the flexible substrate 60. In this embodiment, a distance (height) from an upper surface 90u of the underlayer 90 to an end 60e of the flexible substrate 60 is employed as a criterion of the amount of warp W of the flexible substrate 60. In the flexible substrate 60 on which the chromium layer 10 is formed, this amount of warp W is desirably small.

For example, even with the MF discharge method, the amount of warp W is 30 mm when the chromium layer 10 is formed on the flexible substrate 60 in a state in which the water partial pressure is 3.7×10⁻⁴ Pa as shown in FIG. 7B. In contrast, the amount of warp W is 1 mm when the chromium layer 10 is formed on the flexible substrate 60 in a state in which the water partial pressure is 3.0×10⁻⁴ Pa or less with the MF discharge method. For example, the amount of warp W is 1 mm when the chromium layer 10 is formed on the flexible substrate 60 in a state in which the water partial pressure is 2.6×10⁻⁴ Pa or 2.4×10⁻⁴ Pa. Thus, when the chromium layer 10 is formed on the flexible substrate 60, it is favorable that the water partial pressure inside the vacuum chamber 70 (spaces 21s and 25s) is set to 3.0×10⁻⁴ Pa or less.

Further, even if the water partial pressure is 3.0×10⁻⁴ Pa or less, the amount of warp W is 10 mm when the chromium layer 10 is formed on the flexible substrate 60 by using the RF discharge method (13.56 MHz) as the discharge method as shown in FIG. 7C. In contrast, the amount of warp W is 1 mm when the chromium layer 10 is formed on the flexible substrate 60 by using the MF discharge method (35 kHz) as the discharge method at the water partial pressure of 3.0×10⁻⁴ Pa or less. Thus, when the chromium layer 10 is formed on the flexible substrate 60, it is favorable that the MF discharge method is employed rather than the RF discharge method.

Further, the amount of warp W is higher in comparison with the MF discharge method when the chromium layer 10 is formed on the flexible substrate 60 by using the discharge method as the pulse DC discharge method even if the water partial pressure is 3.0×10⁻⁴ Pa or less as shown in FIG. 7D. For example, the amount of warp W in the pulse DC discharge method is 20 mm. Here, the deposition time in the pulse DC discharge method is 90 seconds. Further, the pulse frequency is 29 kHz.

Provided that the chromium layer is formed on the flexible substrate in each discharge of one pulse of the pulse DC discharge method and the chromium layer formed in each discharge of one pulse is stacked on the flexible substrate for 90 seconds, it can be considered that the chromium layer based on the pulse DC discharge method shown in FIG. 7D is formed of 2.6×10⁶ (29 kHz×90 seconds) layers.

On the other hand, the deposition time in the MF discharge method is 400 seconds. Further, the discharge frequency is 35 kHz and two chromium targets are provided. Thus, provided that the chromium layer 10 is formed on the flexible substrate 60 in each voltage peak of the MF discharge method and this chromium layer 10 formed in each peak is stacked on the flexible substrate 60 for 400 seconds, it can be considered that the chromium layer 10 of the MF discharge method is formed of 2.8×10⁷ (35 kHz×400 seconds33 2) layers.

That is, the number of layers in the MF discharge method according to this embodiment is ten or more times as large as that in the pulse DC discharge method. In addition, in accordance with the dual cathode sputter source, sputtered particles enter the flexible substrate 60 in more random directions in comparison with the pulse DC method, which causes the orientations of crystals of the chromium layer 10 to be more random in comparison with the pulse DC method. With this, the compressive stress of the chromium layer 10 according to this embodiment is reduced in comparison with the pulse DC method.

In this manner, in this embodiment, the compressive stress of the chromium layer 10 formed on the flexible substrate 60 is further reduced, and deformation of the flexible substrate 60 is suppressed as much as possible.

### SECOND EMBODIMENT

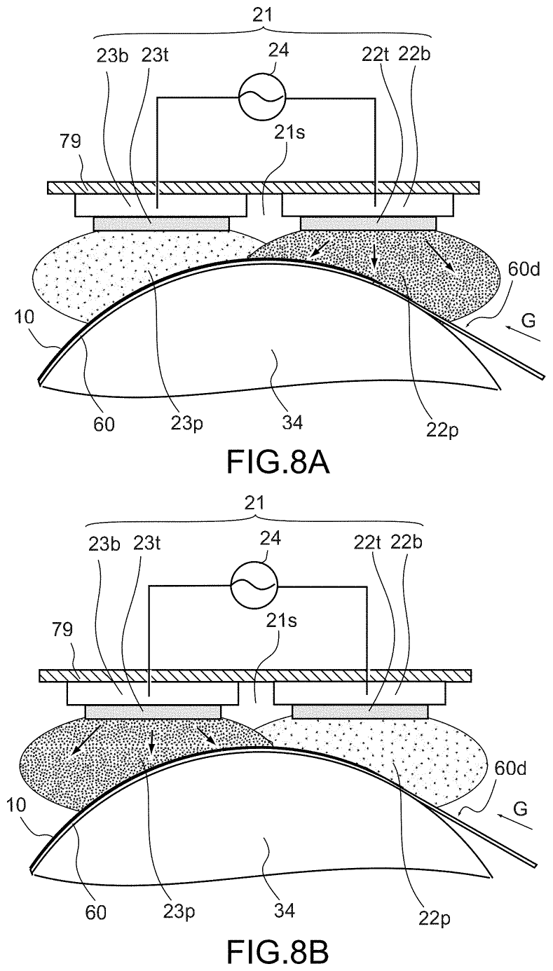

FIGS. 8A and 8B are schematic configuration diagrams of a deposition apparatus according to a second embodiment.

In FIGS. 8A and 8B, a periphery of the deposition source 21 is shown as an example. The deposition source 25 also has the same configuration as the deposition source 21.

In the deposition source 21 shown in FIGS. 8A and 8B, a target surface of the chromium target 22t is disposed in parallel with a target surface of the chromium target 23t. For example, a support 79 that supports the chromium target 22t and the chromium target 23t is flat, not bent, between the chromium target 22t and the chromium target 23t.

With this, during MF discharge, sputtered particles emitted from the chromium target 22t and sputtered particles emitted from the chromium target 23t alternately enter the flexible substrate 60 and, in addition, an incident angle to the flexible substrate 60 is wider. Thus, sputtered particles easily enter the flexible substrate 60 in much more random directions and the compressive stress of the chromium layer 10 is further reduced.

Although the embodiments of the present invention have been described above, the present invention is not limited only to the above-mentioned embodiments and various modifications can be made as a matter of course.

### REFERENCE SIGNS LIST

1, 2 roll-to-roll deposition apparatus

5 loading apparatus

6 pre-processing apparatus

7 cooling apparatus

8 winding apparatus

10 chromium layer

21, 25 deposition source

21s, 25s, 81s, 82s space

22t, 23t, 26t, 27t chromium target

22b, 23b, 26b, 27b backing plate

22p, 23p plasma

24, 28 AC power supply

30 film-transferring mechanism

31, 32, 33a, 33b, 33c, 33d guide roller

34 main roller

51, 55 water partial pressure detecting mechanism

52, 56 gas monitor

53, 57 pipe

60 flexible substrate

60d deposition surface

60e end

70 vacuum chamber

70a inlet

70b outlet

71A, 71B, 71C, 71D, 71E exhaust line

72 gas supply line

73, 74, 75, 76, 80 adhesion preventing plate

77, 78, 79 support

83, 84 target

90 underlayer

90u upper surface

100 deposition apparatus

101a, 101b, 101c connecting channel

1. A deposition method, comprising:
performing pre-treatment of exhausting a vacuum chamber until a water partial pressure inside the vacuum chamber becomes 3.0×10⁻⁴ Pa or less;
causing a flexible substrate to transfer inside the vacuum chamber; and
generating plasma by applying an alternate current (AC) voltage of 1.0 W/cm² or more and 3.0 W/cm² or less at a frequency of 10 kHz or more and 100 kHz or less between a first chromium target and a second chromium target and forming a chromium layer on a deposition surface of the flexible substrate facing the first chromium target and the second chromium target, the first chromium target and the second chromium target being disposed inside the vacuum chamber,
the first chromium target and the second chromium target facing the deposition surface of the flexible substrate, and the first chromium target and the second chromium target being arranged along a transfer direction of the flexible substrate.

2. (canceled)

3. The deposition method according to claim 1, wherein
the pre-treatment further includes a step of heating the flexible substrate to be at 60° C. or more and 180° C. or less.

4. The deposition method according to claim 1, wherein
the pre-treatment further includes a step of performing pre-discharge by applying the AC voltage between the first chromium target and the second chromium target.

5-6. (canceled)

7. The deposition method according to claim 1, wherein
a target surface of the first chromium target is disposed in parallel with a target surface of the second chromium target.

8. The deposition method according to claim 1, wherein
a polyimide film is used as the flexible substrate.

9. A roll-to-roll deposition apparatus, comprising:
a vacuum chamber that maintains a reduced pressure state;
a water partial pressure detecting mechanism that measures a water partial pressure inside the vacuum chamber;
an exhaust mechanism that exhausts the vacuum chamber until the water partial pressure inside the vacuum chamber, the water partial pressure is measured by the water partial pressure detecting mechanism, becomes 3.0×10⁻⁴ Pa or less;
a film-transferring mechanism that causes a flexible substrate to transfer inside the vacuum chamber; and
a deposition source including a first chromium target and a second chromium target, the first chromium target and the second chromium target facing a deposition surface of the flexible substrate that transfers inside the vacuum chamber and the first chromium target and the second chromium target being arranged along a transfer direction of the flexible substrate, the deposition source generating plasma by applying an AC voltage of 1.0 W/cm² or more and 3.0 W/cm² or less at a frequency of 10 kHz or more and 100 kHz or less between the first chromium target and the second chromium target and forming a chromium layer on the deposition surface.
